(19) United States
(12) Patent Application Publication
(10) Pub. No.: US 2005/0145956 A1
(43) Pub. Date: Jul. 7, 2005

(54) Devices with high-k gate dielectric

(75) Inventors: Chih-Hao Wang, Hsin-Chu (TW); Chenming Hu, Alamo, CA (US)

Correspondence Address: STEPHEN B. ACKERMAN, 28 DAVIS AVENUE, POUGHKEEPSIE, NY, 12603, US

(73) Assignee: Taiwan Semiconductor Manufacturing Co.

(21) Appl. No.: 10/751,794

(22) Filed: Jan. 5, 2004

(51) Int. Cl. H01L 29/94; H01L 21/3205

(52) U.S. Cl. 257/410; 257/411; 438/591; 438/954

(57) ABSTRACT

A gate electrode is formed including a gate conductor overlying a high dielectric constant (k) gate dielectric. A small or round substrate recess of controlled depth is formed around the gate electrode. This controlled substrate recess will improve current drive degradation performance of the device.

### BACKGROUND OF THE INVENTION

(1) Field of the Invention

The present invention relates to the fabrication of integrated circuit devices, and more particularly, to a method of forming a gate electrode having a high dielectric constant gate dielectric where small or round recesses into the substrate adjacent to the gate minimize current drive degradation in the fabrication of integrated circuits.

(2) Description of the Prior Art

In the fabrication of integrated circuits, patterning and etching techniques are used to form structures such as polysilicon gates. A gate dielectric is deposited over a substrate followed by a gate conductive material, such as polysilicon. The gate conductive material and the gate dielectric are etched away except where they are covered by a mask, for example, to leave the patterned gate electrode. Currently, devices having high dielectric constant (k) gate dielectrics exhibit either no recessing of the substrate adjacent to the gate or severe substrate recessing. It is very difficult to fabricate devices without any silicon recess because a certain amount of high dielectric constant dielectric overetch is necessary to remove all residue. On the other hand, severe recesses degrade device current drive significantly. It is desired to provide a method to form devices where a small or round substrate recess is formed to minimize current drive degradation.

U.S. Pat. No. 6,063,698 to Tseng et al teaches a high-k gate dielectric and no recess. U.S. Pat. No. 6,451,647 to Yang et al discloses a method of removing high-k dielectric layer residue by a low power plasma cleaning process so no recess is formed. U.S. Pat. No. 6,479,403 to Tsei et al teaches using a high-k gate dielectric that is patterned before the gate material is patterned wherein no recess is formed.

A number of papers address the subject of high-k dielectrics. “Conventional n-channel MOSFET devices using single layer HfO₂ and ZrO₂ as high-k gate dielectrics with polysilicon gate electrode” by Y. Kim et al, IEDM 2001, p. 455-458, “Effect of Polysilicon Gate on the Flatband Voltage Shift and Mobility Degradation for ALD-Al2O3 Gate Dielectric” by J. H. Lee et al, IEDM 2000, pp. 645-648, “Mobility Enhancement in Strained Si NMOSFETs with HfO₂ Gate Dielectrics”, by K. Rim et al, 2002 Symposium on VLSI Technology Digest of Technical Papers, pp. 12-13, “Low Standby Power CMOS with HfO₂ Gate Oxide for 100-nm Generation”, by S. Pidin et al, 2002 Symposium on VLSI Technology Digest of Technical Papers, pp. 28-29, “Poly-Si Gate CMOSFETs with HfO₂—Al₂O₃ Laminate Gate Dielectric for Low Power Applications” by J. H. Lee et al, 2002 Symposium on VLSI Technology Digest of Technical Papers, pp. 85-86 show no recess. “80 nm Poly-Si Gate CMOS with HfO₂ gate Dielectric”, by C. Hobbs et al, IEDM 2001, pp. 651-654 shows a large recess that is not rounded. “Advanced CMOS Transistors with a Novel HfSiON Gate Dielectric” by A. L. P. Rotondaro et al, 2002 Symposium on VLSI Technology Digest of Technical Papers, pp. 148-149 shows a severe recess that is not rounded.

### SUMMARY OF THE INVENTION

Accordingly, it is a primary object of the invention to provide an effective and very manufacturable process for forming devices having high dielectric constant gate dielectric in the fabrication of integrated circuits.

Another object of the invention is to form gate electrodes having high dielectric constant gate dielectric wherein current drive degradation is minimized.

A further object of the invention is to form gate electrodes having high dielectric constant gate dielectric wherein small or round recesses are formed in the substrate adjacent to the gate electrodes thereby minimizing current drive degradation.

In accordance with the objects of the invention, a new method for forming gate electrodes having high dielectric constant gate dielectric wherein small or round recesses are formed in the substrate adjacent to the gate electrodes is achieved. A gate electrode is formed including a gate conductor overlying a high dielectric constant (k) gate dielectric. A high-k gate dielectric is provided on a substrate. The gate conductor and high-k gate dielectric are etched and a substrate recess is formed having a controlled depth.

Also in accordance with the objects of the invention, a new method for forming gate electrodes having high dielectric constant gate dielectric wherein current drive degradation is minimized is achieved. A high-k gate dielectric is provided on a substrate. A gate conductor is provided overlying said high-k gate dielectric. The gate conductor is etched to form a gate electrode. Spacers are formed on sidewalls of the gate electrode and overlying the high-k gate dielectric layer. Thereafter, the high-k gate dielectric not covered by the gate electrode and the spacers is etched away and small or round recesses are formed within the substrate. Raised source/drain regions may be formed.

Also in accordance with the objects of the invention, a semiconductor device having minimal current drive degradation is achieved. The semiconductor device comprises a silicon substrate, a high-k gate dielectric on the silicon substrate, a gate conductor overlying the high-k gate dielectric, and a substrate recess in the silicon substrate adjacent to the semiconductor device. Raised source/drain regions may be formed.

### BRIEF DESCRIPTION OF THE DRAWINGS

In the accompanying drawings forming a material part of this description, there is shown:

FIGS. 1 through 5 are cross-sectional representations of a first preferred embodiment of the present invention.

FIGS. 6 through 9 are cross-sectional representations of a second preferred embodiment of the present invention.

FIG. 10 is a cross-sectional representation of a completed integrated circuit device of the present invention.

### DESCRIPTION OF THE PREFERRED EMBODIMENTS

The process of the present invention can be used in any application using high dielectric constant dielectrics. The process can be used to form bit lines, word lines, polysilicon gate electrodes, and the like. The drawing FIGS. 1-5 and 6-9 illustrate the process of the invention in making a polysilicon gate electrode. It will be appreciated by those skilled in the art that the process of the invention can be used to make any structure where high-k dielectrics and etching are used to form the structure.

A first preferred embodiment of the present invention will be described with reference to FIGS. 1-5. Referring now more particularly to FIG. 1, there is shown a semiconductor substrate 10. This may be a monocrystalline silicon (Si) substrate, a monocrystalline germanium (Ge) substrate, a monocrystalline silicon germanium (SiGe) substrate, a silicon-on-insulator (SOI) substrate, a germanium-in-insulator substrate, or a silicon germanium-on-insulator substrate, for example. A high-k dielectric layer 14 is deposited over the surface of the substrate to a thickness of between about 5 and 100 Angstroms. The dielectric constant should be larger than 3.9. For example, the high-k material may be oxides of hafnium, zirconium, cerium, aluminum, titanium, yttrium, and transition metals; silicates of hafnium, zirconium, cerium, aluminum, titanium, yttrium, and transition metals; barium strontium titanate, ferroelectrics; and combinations or multi-layers of the these high-k materials.

Now, a gate conductor layer 16 is deposited over the high-k dielectric 14. The gate conductor layer may be polysilicon, polysilicon-germanium, metal, metal oxide, metal nitride, silicide, or a stack of these layers. The gate conductor layer has a thickness of between about 200 and 2000 Angstroms.

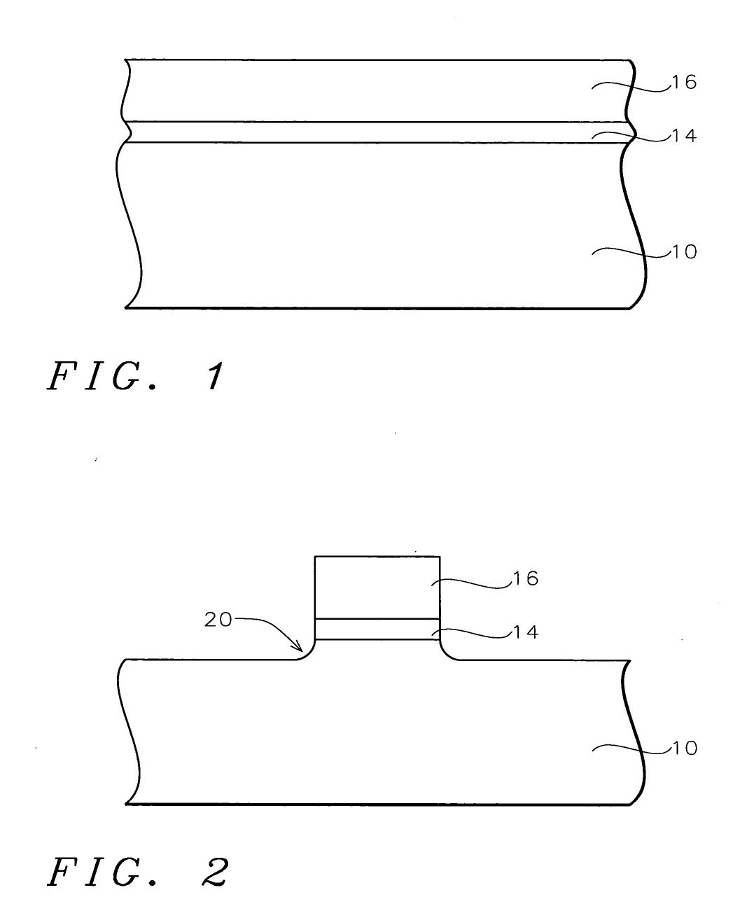

Now, as shown in FIG. 2, the gate conductor material 16 and the high-k dielectric layer 14 are etched to form a gate electrode. Etching continues until a substrate recess is formed adjacent to the gate electrode.

It is difficult to fabricate devices without any silicon recess because a certain amount of overetch is necessary to remove all of the high-k dielectric residue. However, severe recesses will degrade device current drive significantly.

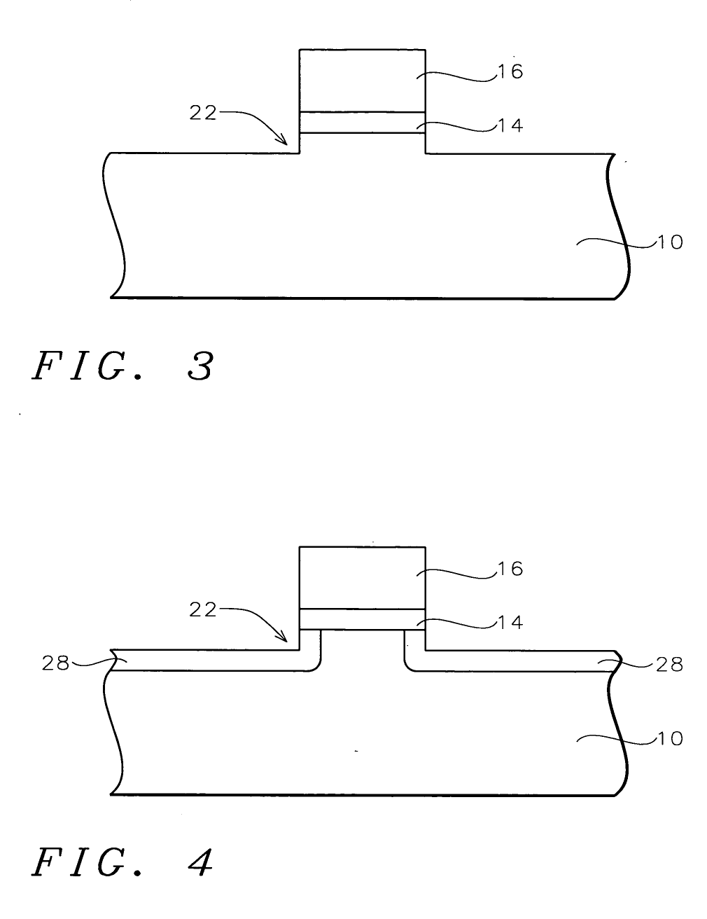

According to the process of the present invention, small or rounded recesses are formed into the silicon substrate. FIG. 2 illustrates rounded recesses 20 while FIG. 3 illustrates small recesses 22 that are not rounded. The small recesses 22 should have a depth into the silicon 10 of less than about 30 Angstroms. Rounded recesses 20 can be deeper than 30 Angstroms. It has been found that rounded recesses show much less drive degradation than non-rounded recesses. No recess is preferred, but very difficult to form. Rounded recesses and small recesses are acceptable due to smaller current drive degradation. This etching process assures removal of all high-k dielectric residue from the surface of the substrate.

Now, referring to FIG. 4, source/drain extensions 28 are formed using a tilt angle implant. For example, As (and P) ions are implanted at a tilt angle of between about 1 and 75 degrees and preferably between 5 and 15 degrees. A tilt angle implantation will improve the current drive degradation caused by the recess, but non-tilt angle implantation may alternatively be used.

Spacers 40 are formed on the sidewalls of the gate electrode. For example, a conformal layer of oxide, nitride, complex, or multi-layer is deposited over the gate electrode 16 and the substrate. The layer is anisotropically etched back to leave spacers 40 on the sidewalls of the gate electrode.

Referring now to FIG. 5, raised source/drains 44 are formed by epitaxial silicon, epitaxial germanium, germanium or silicon carbon growth on the silicon substrate. Preferably, the source/drain thickness should be less than about 800 Angstroms. This thickness will avoid bridging.

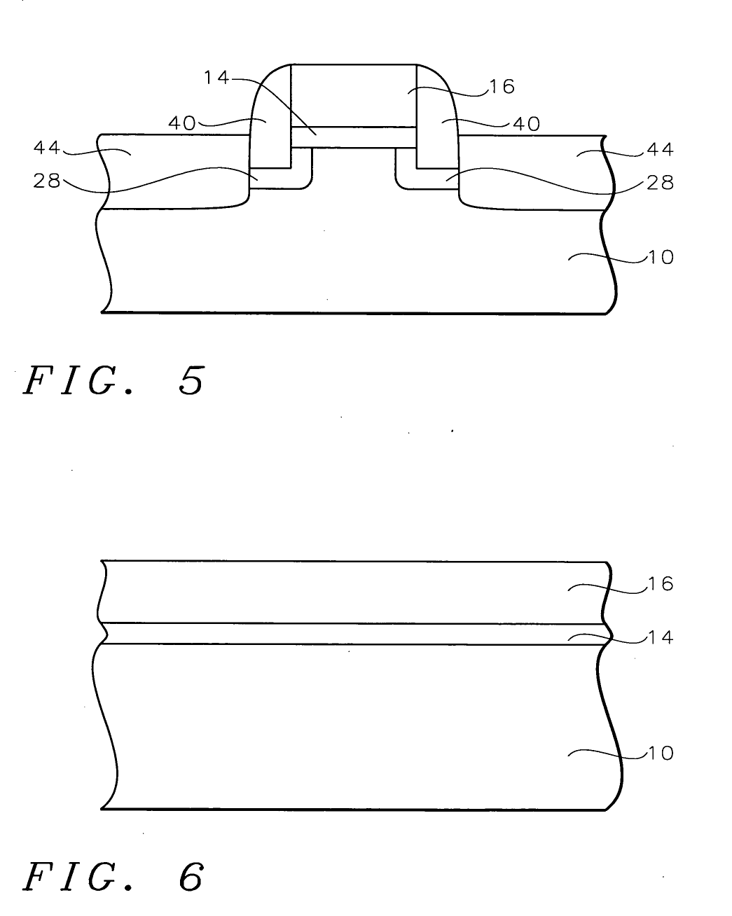

Now, a second preferred embodiment of the present invention will be described with reference to FIGS. 6-9. FIG. 6 shows a semiconductor substrate 10 which may be a monocrystalline silicon (Si) substrate, a monocrystalline germanium (Ge) substrate, a monocrystalline silicon germanium (SiGe) substrate, a silicon-on-insulator (SOI) substrate, a germanium-in-insulator substrate, or a silicon germanium-on-insulator substrate, for example. A high-k dielectric layer 14 is deposited over the surface of the substrate to a thickness of between about 5 and 100 Angstroms. The dielectric constant should be larger than 3.9. For example, the high-k material may be oxides of hafnium, zirconium, cerium, aluminum, titanium, yttrium, and transition metals; silicates of hafnium, zirconium, cerium, aluminum, titanium, yttrium, and transition metals; barium strontium titanate, ferroelectrics; and combinations or multi-layers of the these high-k materials.

Now, a gate conductor layer 16 is deposited over the high-k dielectric 14. The gate conductor layer may be polysilicon, polysilicon-germanium, metal, metal oxide, metal nitride, silicide, or a stack of these layers. The gate conductor layer has a thickness of between about 200 and 2000 Angstroms.

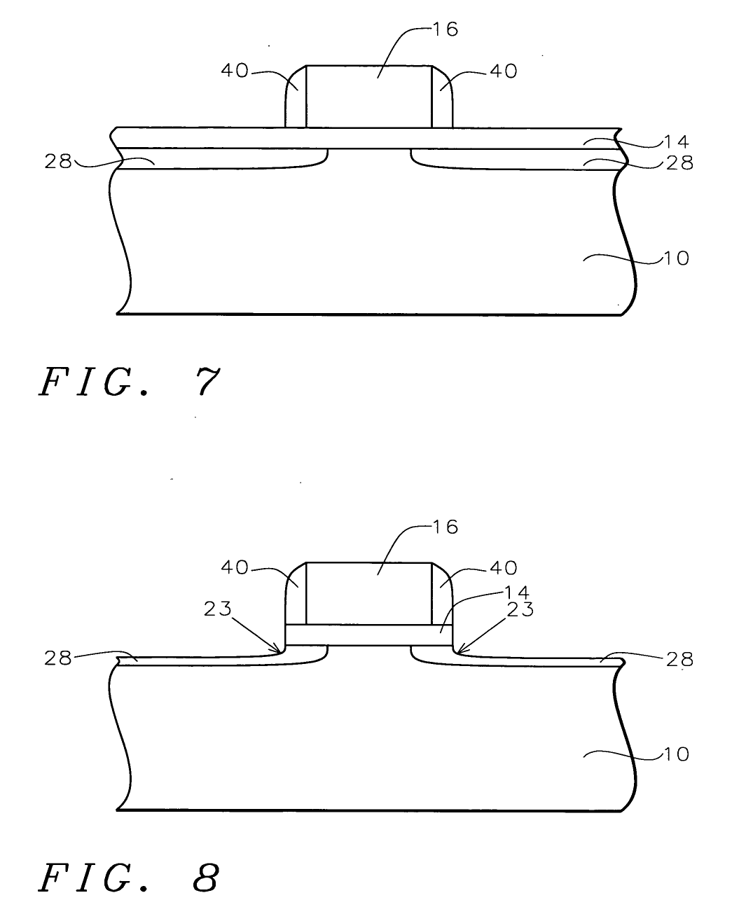

Referring now to FIG. 7, the-gate conductor layer 16 is patterned to form the gate electrode. Spacers 40 are formed on the sidewalls of the gate electrode. For example, a conformal layer of oxide, nitride, complex, or multi-layer is deposited over the gate electrode 16 and the substrate. The layer is anisotropically etched back to leave spacers 40 on the sidewalls of the gate electrode. Source/drain extensions 28 are implanted prior to spacer formation. A tilt angle implantation will improve the current drive degradation caused by the recess, but non-tilt angle implantation may alternatively be used.

Referring now to FIG. 8, the high-k dielectric layer 14 is etched away where it is not covered by the gate electrode 16 and spacers 40. Now, according to the process of the present invention, small or rounded recesses 23 are formed into the silicon substrate, as shown in FIG. 8. The small recesses should have a depth into the silicon 10 of less than about 30 Angstroms. Rounded recesses can be deeper than 30 Angstroms. It has been found that rounded recesses show much less drive degradation than non-rounded recesses.

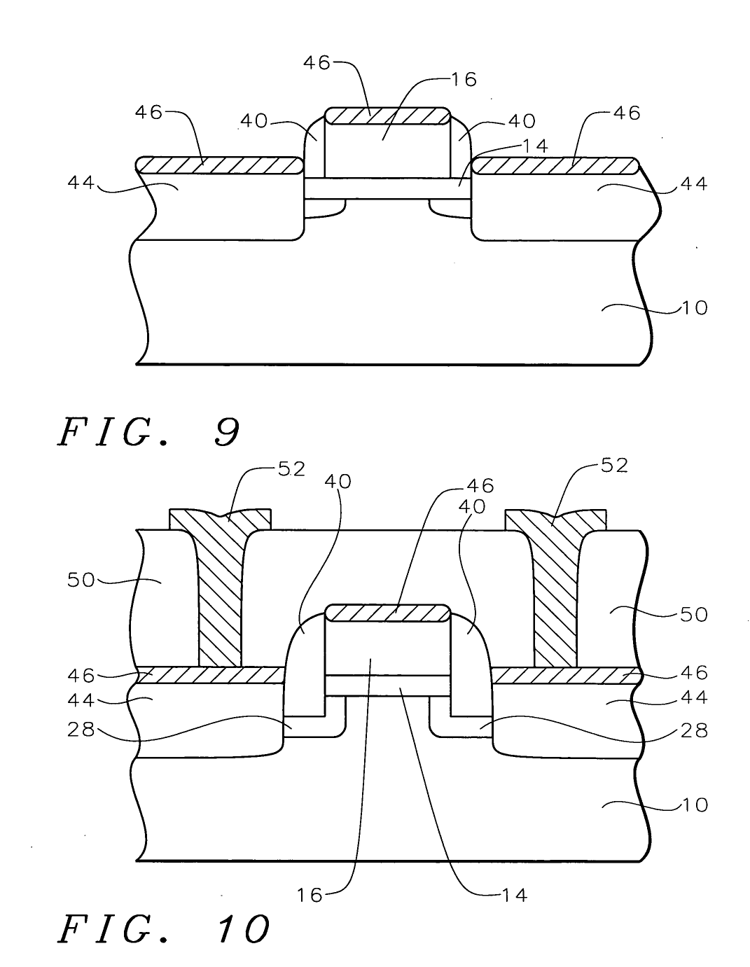

Referring now to FIG. 9, raised source/drains 44 are formed by Si, SiGe, SiC, or Ge grown on the silicon substrate. Preferably, the source/drain thickness should be less than about 800 Angstroms.

Now, a blocking layer of oxide, oxynitride, or other similar film is formed on areas of the substrate that are not to be silicided. Silicide may be formed on most of the gate electrode and source/drain regions for MOSFET devices. The blocking layer will prevent formation of silicide on some of the gate electrode and source/drain regions, for example, for poly resistance. This is dependent on the purpose of the designed structure, pattern, or layout. For example, silicide 46 is formed as shown in FIG. 9.

Processing continues as is conventional in the art to complete the integrated circuit device. For example, as shown in FIG. 10, a dielectric layer 50 is formed over the gate electrode 16 and raised source/drain 44. An electrical connection is made to the source/drain regions, for example, by metal plugs 52. FIG. 10 illustrates the completion of FIG. 5 of the first embodiment. It will be understood that the device of FIG. 9 can be completed as shown in FIG. 10 as well.

The present invention provides a process for forming high-k gate dielectric devices having minimized drive current degradation. This is achieved by forming small or rounded silicon recesses adjacent to the devices or raised source/drain regions.

While the invention has been particularly shown and described with reference to the preferred embodiments thereof, it will be understood by those skilled in the art that various changes in form and details may be made without departing from the spirit and scope of the invention.

1. A semiconductor device comprising:
a semiconductor substrate;
a high-k gate dielectric on said semiconductor substrate;
a gate conductor overlying said high-k gate dielectric; and
a substrate recess in said semiconductor substrate adjacent to said high-k gate dielectric wherein said substrate recess has a controlled depth.

2. The device according to claim 1 wherein said dielectric constant of said high-k gate dielectric is larger than about 3.9.

3. The device according to claim 1 wherein said gate conductor comprises polysilicon, polysilicon germanium, metal, metal oxide, metal nitride, silicide, or a stack of a plurality of these layers.

4. The device according to claim 1 wherein said substrate recess is rounded and wherein said controlled depth is less than about 100 Angstroms.

5. The device according to claim 1 wherein said substrate recess has a depth of less than about 30 Angstroms.

6. The device according to claim 1 wherein said semiconductor substrate is-a silicon (Si) substrate, a germanium (Ge) substrate, a silicon germanium (SiGe) substrate, a silicon-on-insulator (SOI) substrate, a germanium-on-insulator substrate, or a silicon germanium-on-insulator substrate.

7. A method of manufacturing an integrated circuit including a gate structure on a substrate, said gate structure including a gate conductor overlying a high dielectric constant (k) gate dielectric, said method comprising the steps of:
providing said high-k gate dielectric on said substrate;
providing said gate conductor on said gate dielectric;
patterning said gate conductor and said high-k gate dielectric to form a gate electrode wherein a substrate recess is formed having a controlled depth;
forming spacers on sidewalls of said gate electrode; and
forming raised source/drain regions.

8. The method according to claim 7 wherein said dielectric constant of said high-k dielectric is larger than about 3.9.

9. The method according to claim 7 wherein said gate conductor comprises polysilicon, polysilicon germanium, metal, metal oxide, metal nitride, silicide, or a stack of a plurality of these layers.

10. The method according to claim 7 wherein said raised source/drain regions have a thickness smaller than 800 Angstroms.

11. The method according to claim 7 wherein said step of forming said raised source/drain regions comprises: epitaxially growing silicon, silicon germanium, germanium, or silicon carbide on said substrate surface.

12. The method according to claim 7 further comprising forming source/drain extensions in said substrate.

13. The method according to claim 7 wherein said substrate recess is rounded and wherein said controlled depth is less than about 100 Angstroms.

14. The method according to claim 7 wherein said recess has a depth of less than about 30 Angstroms.

15. A method of manufacturing an integrated circuit including a gate structure on a substrate, said gate structure including a gate conductor overlying a high dielectric constant (k) gate dielectric, said method comprising the steps of:
providing said high-k gate dielectric on said substrate;
providing said gate conductor on said gate dielectric;
patterning said gate conductor to form a gate electrode;
forming spacers on sidewalls of said gate electrode and overlying said high-k gate dielectric layer;
thereafter etching away said high-k gate dielectric not covered by said gate electrode and said spacers wherein a substrate recess having a controlled depth is formed; and
forming raised source/drain regions.

16. The method according to claim 15 wherein said dielectric constant of said high-k dielectric is larger than about 3.9.

17. The method according to claim 15 wherein said gate conductor comprises polysilicon, polysilicon germanium, metal, metal oxide, metal nitride, silicide, or a stack of a plurality of these layers.

18. The method according to claim 15 wherein said raised source/drain regions have a thickness smaller than 800 Angstroms.

19. The method according to claim 15 wherein said step of forming said raised source/drain regions comprises: epitaxially growing silicon, silicon germanium, germanium, or silicon carbide on said substrate surface.

20. The method according to claim 15 further comprising forming source/drain extensions in said substrate.

21. The method according to claim 15 wherein said substrate recess is rounded and wherein said controlled depth is less than about 100 Angstroms.

22. The method according to claim 15 wherein said substrate recess has a depth of less than about 30 Angstroms.

23. A semiconductor device comprising:
a semiconductor substrate;
a gate electrode on said semiconductor substrate having a high-k gate dielectric; and
a substrate recess in said semiconductor substrate adjacent to said gate electrode wherein said substrate recess has a controlled depth of less than 100 Angstroms.

24. The device according to claim 23 wherein said dielectric constant of said high-k gate dielectric is larger than about 3.9.

25. The device according to claim 23 wherein said gate electrode comprises polysilicon, polysilicon germanium, metal, metal oxide, metal nitride, silicide, or a stack of a plurality of these layers.

26. The device according to claim 23 wherein said substrate recess is rounded.

27. The device according to claim 23 wherein said substrate recess has a depth of less than about 30 Angstroms.

28. The device according to claim 23 wherein said semiconductor substrate is a silicon (Si) substrate, a germanium (Ge) substrate, a silicon germanium (SiGe) substrate, a silicon-on-insulator (SOI) substrate, a germanium-on-insulator substrate, or a silicon germanium-on-insulator substrate.
